(19) United States
(12) Patent Application Publication
(10) Pub. No.: US 2012/0181613 A1
(43) Pub. Date: Jul. 19, 2012

(54) Methods for Forming Field Effect Transistor Devices With Protective Spacers

(75) Inventors: Veeraraghavan S. Basker, Schenectady, NY (US); Toshiharu Furukawa, Essex Junction, VT (US); Steven J. Holmes, Guilderland, NY (US); Sivananda K. Kanakasabapathy, Niskayuna, NY (US)

(73) Assignee: INTERNATIONAL BUSINESS MACHINES CORPORATION, Armonk, NY (US)

(21) Appl. No.: 13/009,271

(22) Filed: Jan. 19, 2011

(51) Int. Cl. H01L 27/088; H01L 21/8234; H01L 21/8238

(52) U.S. Cl. 257/368; 438/231; 438/305; 257/E21.632; 257/E21.619; 257/E27.06

(57) ABSTRACT

A method for forming a field effect transistor device includes forming a first gate stack and a second gate stack on a substrate, depositing a first photoresist material over the second gate stack and a portion of the substrate, implanting ions in exposed regions of the substrate to define a first source region and a first drain region adjacent to the first gate stack, depositing a first protective layer over the first source region, the first gate stack, the first drain region, and the first photoresist material, removing portions of the first protective layer to expose the first photoresist material and to define a first spacer disposed on a portion of the first source region and a portion of the first drain region, removing the first photoresist material, and removing the first spacer.

### BACKGROUND

The present invention relates to integrated circuits, and more specifically, to methods for forming field effect transistors in integrated circuits.

Integrated circuits often include a number of different types of field effect transistor (FET) devices formed on a substrate. The FET devices include a gate stack disposed on a substrate and a source and drain region in the substrate. The different types of FET devices may include different doping profiles in the source and drain regions of the devices.

A method for more effectively forming the source and drain regions of different types of devices on a substrate is desired.

### BRIEF SUMMARY

According to one embodiment of the present invention, a method for forming a field effect transistor device includes forming a first gate stack and a second gate stack on a substrate, depositing a first photoresist material over the second gate stack and a portion of the substrate, implanting ions in exposed regions of the substrate to define a first source region and a first drain region adjacent to the first gate stack, depositing a first protective layer over the first source region, the first gate stack, the first drain region, and the first photoresist material, removing portions of the first protective layer to expose the first photoresist material and to define a first spacer disposed on a portion of the first source region and a portion of the first drain region, removing the first photoresist material, and removing the first spacer.

According to another embodiment of the present invention, a field effect transistor device prepared by a process comprising the steps of forming a first gate stack and a second gate stack on a substrate, depositing a first photoresist material over the second gate stack and a portion of the substrate, implanting ions in exposed regions of the substrate to define a first source region and a first drain region adjacent to the first gate stack, depositing a first protective layer over the first source region, the first gate stack, the first drain region, and the first photoresist material, removing portions of the first protective layer to expose the first photoresist material and to define a first spacer disposed on a portion of the first source region and a portion of the first drain region, and removing the first photoresist material.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIGS. 1-12 illustrate a side, cut-away view of a method for forming source and drain regions in FET devices having different doping profiles, in which:

FIG. 1 illustrates a substrate and gate stacks disposed on the substrate;

FIG. 2 illustrates the formation of a photoresist material;

FIG. 3 illustrates the formation of a source region and a drain region;

FIG. 4 illustrates the deposition of a layer of protective spacer material;

FIG. 5 illustrates the removal of portions of the protective spacer material;

FIG. 6 illustrates the resultant structure following the removal of the photoresist material;

FIG. 7 illustrates the resultant structure following the removal of the spacer;

FIG. 8 illustrates the formation of a photoresist material;

FIG. 9 illustrates the deposition of a layer of protective spacer material;

FIG. 10 illustrates the resultant structure following an etching process;

FIG. 11 illustrates the resultant structure following the removal of the photoresist material; and

FIG. 12 illustrates the resultant structure following the removal of the spacer.

### DETAILED DESCRIPTION

Previous methods for forming a variety of field effect transistor (FET) devices included, for example, forming a number of gate stacks on a substrate and doping portions of the substrate using ion implantation to form source and drain regions. For integrated circuits, it is often desirable to form FETs having different doping profiles in the source and drain regions. For example, an integrated circuit may include n-type and p-type FETs that are formed using different doping profiles. To form a variety of FETs on a substrate with different doping profiles, a number of masking and doping steps may be performed. In this regard, a photolithographic mask is patterned over portions of the features on the substrate to protect the portions from ion implantation. The exposed regions are subjected to ion implantation with a desired dopant to form devices with a particular doping profile. The photoresist may then be removed, and another photoresist is patterned to expose different portions of the wafer that are subjected to ion implantation with yet another dopant. The process may be repeated as desired.

During ion implantation, the photoresist absorbs ions, which forms a hardened layer or “crust” over the exposed photoresist resulting in a photoresist that is difficult to remove. A chemical etching process is usually performed to remove the crusted photoresist, however the chemical etching process may damage the silicon substrate (and the doped source and drain regions in the substrate) that are masked by the photoresist by removing portions of the doped silicon material. The removal of the doped silicon material (particularly in the areas of the source and drain regions proximate to the channel region of the device) may undesirably reduce the performance of the effected FET devices.

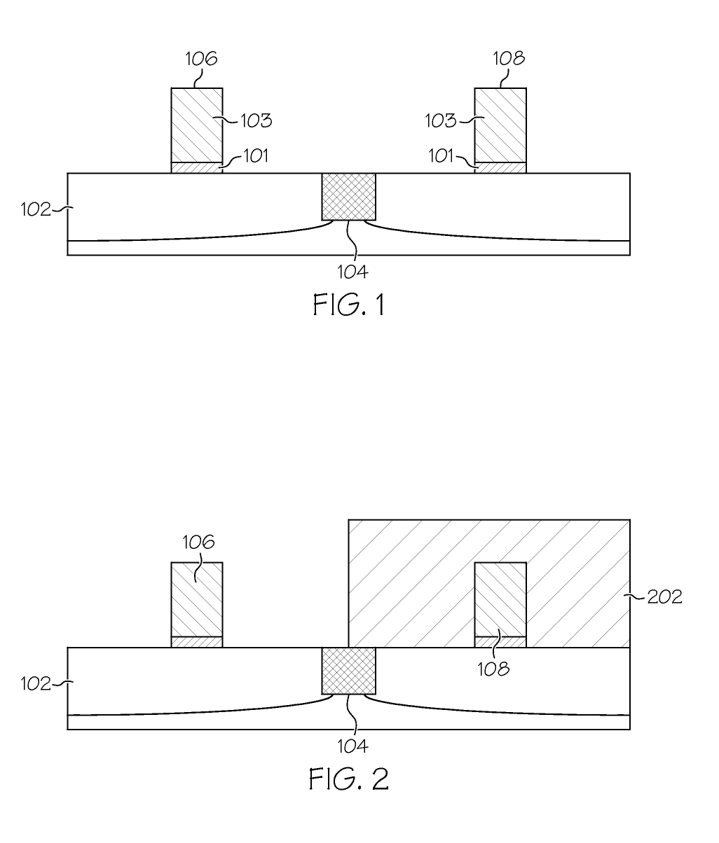

FIGS. 1-12 illustrate a side, cut-away view of a method for forming source and drain regions in FET devices having different doping profiles. A doping profile describes the type of dopants applied to the source and drain regions of a device. In the illustrated embodiment, a device having n-type source and drain regions, and a device having p-type source and drain regions are formed. However, two n-type devices may be formed having different n-type doping profiles, or two p-type devices may be formed having different p-type doping profiles using similar methods. The methods described below illustrate the formation of two FET devices having different doping profiles for illustrative purposes however, similar methods may be used to form any number of FET devices having any number of different doping profiles.

FIG. 1 illustrates a substrate 102 that may be formed from, for example, a silicon material. The substrate 102 includes a shallow trench isolation (STI) region 104. A gate stack 106 and a gate stack 108 have been formed on the substrate 102. The gate stacks 106 and 108 may be formed by any suitable process that may include, for example, material deposition processes (e.g., chemical vapor deposition (CVD) or plasma-enhanced chemical vapor deposition (PECVD)); photolithographic patterning; and etching processes (reactive ion etching (RIE)). In the illustrated embodiment, the gate stacks 106 and 108 include an oxide layer 101 and a polysilicon layer 103. The gate stacks 106 and 108 are shown for illustrative purposes as being similar materials and dimensions, however the gate stacks 106 and 108 may include any type of gate such as, for example, metallic gates, polysilicon gates, or carbon based gates.

FIG. 2 illustrates the formation of a photoresist material 202 that has been formed over the gate stack 108 and portions of the adjacent substrate 102. The photoresist material 202 may be formed using a photolithographic process.

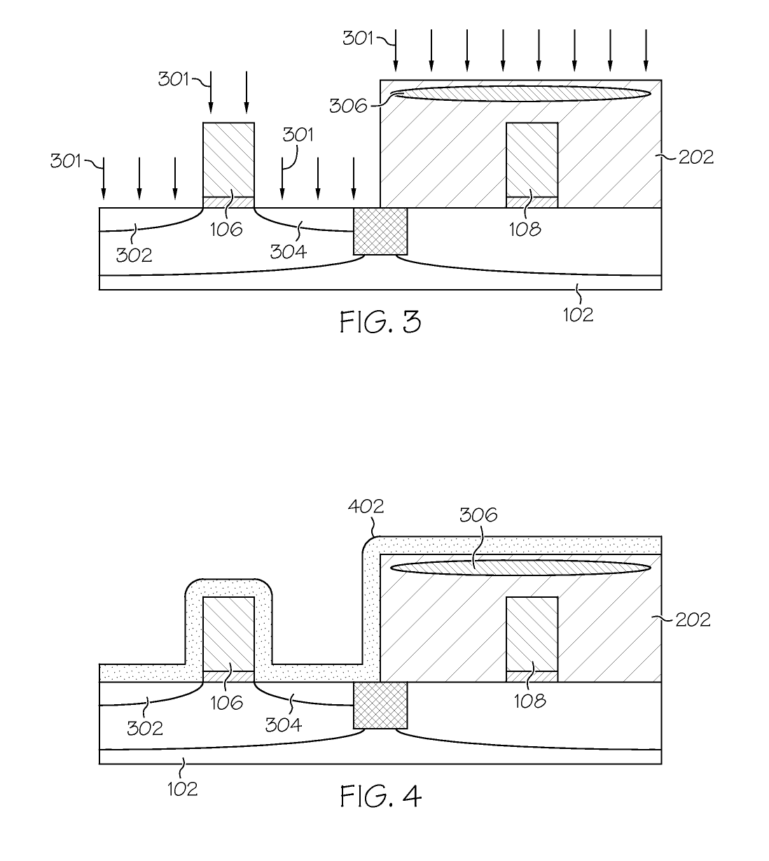

FIG. 3 illustrates the formation of a source region 302 and a drain region 304 using an ion implantation process. In the illustrated embodiment, n-type dopants 301 are implanted in the exposed regions of the substrate 102 resulting in the source region 302 and the drain region 304. The dopants 301 are also absorbed by the photoresist material 202 resulting in a hardened region (a “crust” region) 306.

FIG. 4 illustrates the deposition of a conformal layer of protective spacer material 402 over the exposed source and drain regions 302 and 304, the gate stack 106, and the photoresist material 202. The layer of protective spacer material 402 may include, for example, an oxide material (e.g., a low temperature oxide material), a nitride material, or a carbon based polymer material. The layer 402 may be deposited using, for example, a CVD process or a high aspect ratio process (HARP).

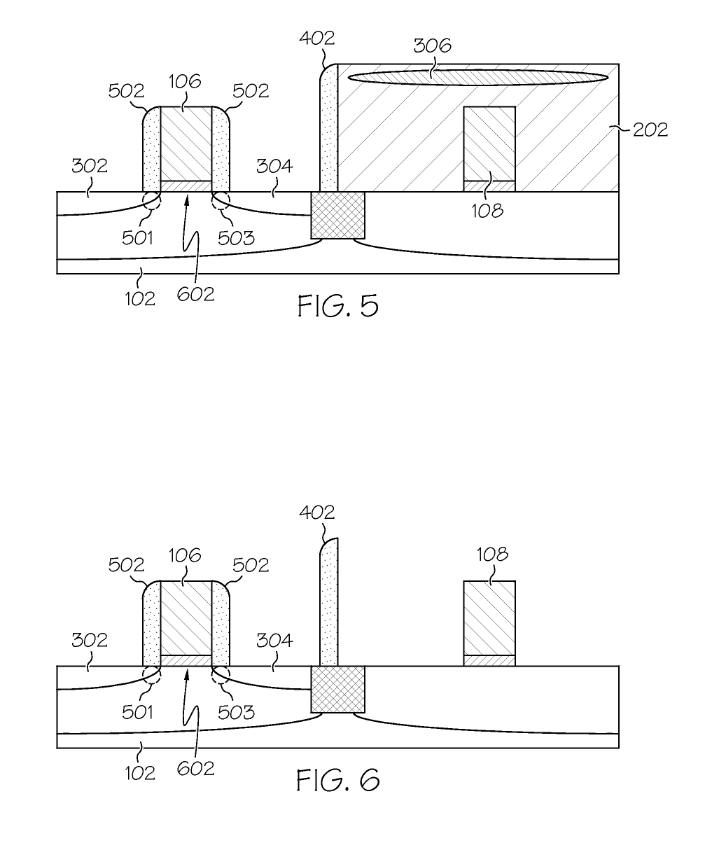

FIG. 5 illustrates the removal of portions of the protective spacer material 402 using an anisotropic etching process such as, for example, RIE. The anisotropic etching process results in the formation of the spacer 502 over the regions 501 and 503 in the source region 302 and the drain region 304 adjacent to the gate stack 106.

FIG. 6 illustrates the resultant structure following the removal of the photoresist material 202 (and the hardened region 306) using an etching process such as, for example, an oxygen RIE process. The spacer 502 protects the regions 501 and 503 of the source region 302 and drain region 304 from being damaged (e.g., portions of the doped silicon material removed) by the etching process, thus preserving the integrity of the doped silicon in the regions 501 and 503 of the source and drain regions 302 and 304 proximate to the channel region 602 (below the gate stack 106) of the device.

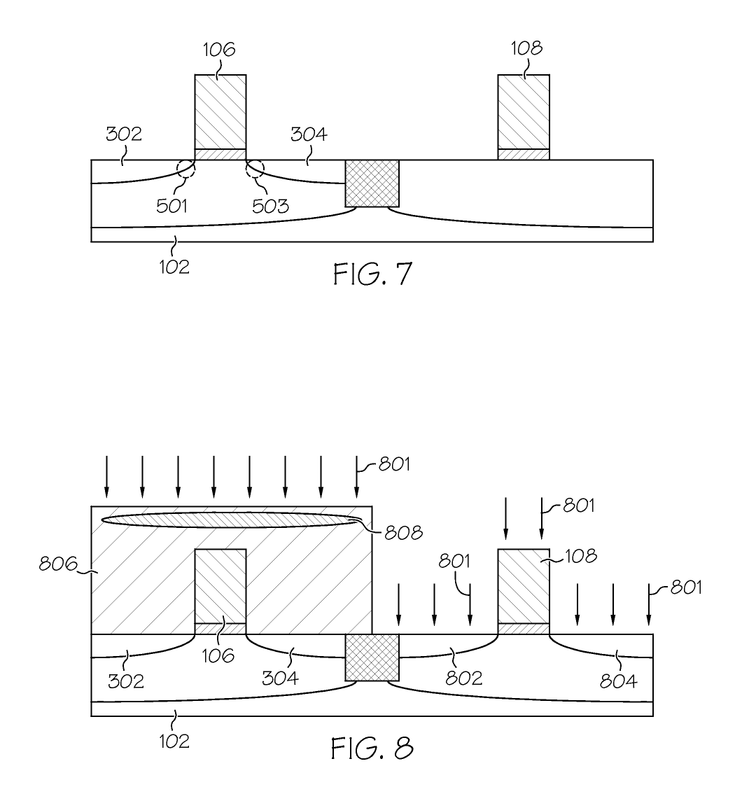

FIG. 7 illustrates the resultant structure following the removal of the spacer 502 (of FIG. 6) and the residual protective spacer material 402 using an etching process. The etching process may include for example, an isotropic dry etching process or a diluted hydrogen fluorine (HF) chemical process depending on the type of material used to form the protective spacer material 402. The etching process that removes the spacer 502 and the residual protective spacer material 402 may be less “aggressive” than the etch used to remove the photoresist material 202 and the hardened region 306. Thus, the regions 501 and 503 remain substantially intact and relatively undamaged following the removal of the spacer 502.

FIG. 8 illustrates the formation of a photoresist material 806 over the gate stack 106 and the source and drain regions 302 and 304 in the substrate 102. The photoresist material 806 is formed using a similar photolithographic method as described above (in the formation of the photoresist material 202 of FIG. 2). Following the formation of the photoresist material 802, ions 801 are implanted in the substrate 102 to form a source region 802 and drain region 804. The ions 801 may be any type of ions suitable for forming a desired doping profile in the source region 802 and drain region 804. The ion implantation process forms a hardened region 808 in the photoresist material 806.

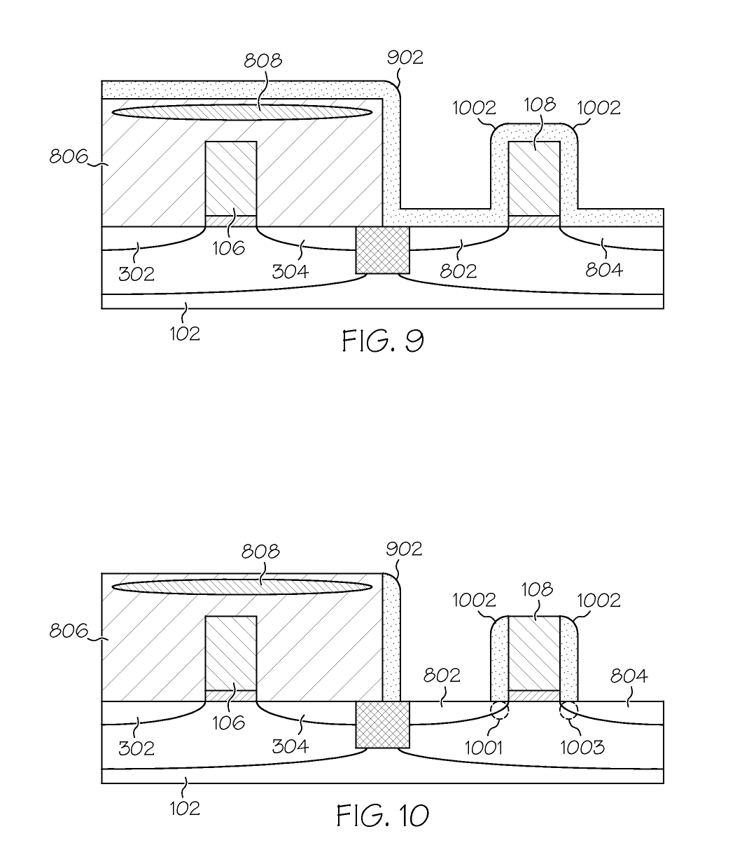

FIG. 9 illustrates the deposition of a conformal layer of protective spacer material 902 over the exposed source and drain regions 802 and 804, the gate stack 108, and the photoresist material 806 using a similar method as described above in FIG. 4.

FIG. 10 illustrates the resultant structure following an anisotropic etching process similar to the process described above in FIG. 5 that removes portions of the protective spacer material 902. The etching process results in the formation of a spacer 1002 over regions 1001 and 1003 of the source and drain regions 802 and 804.

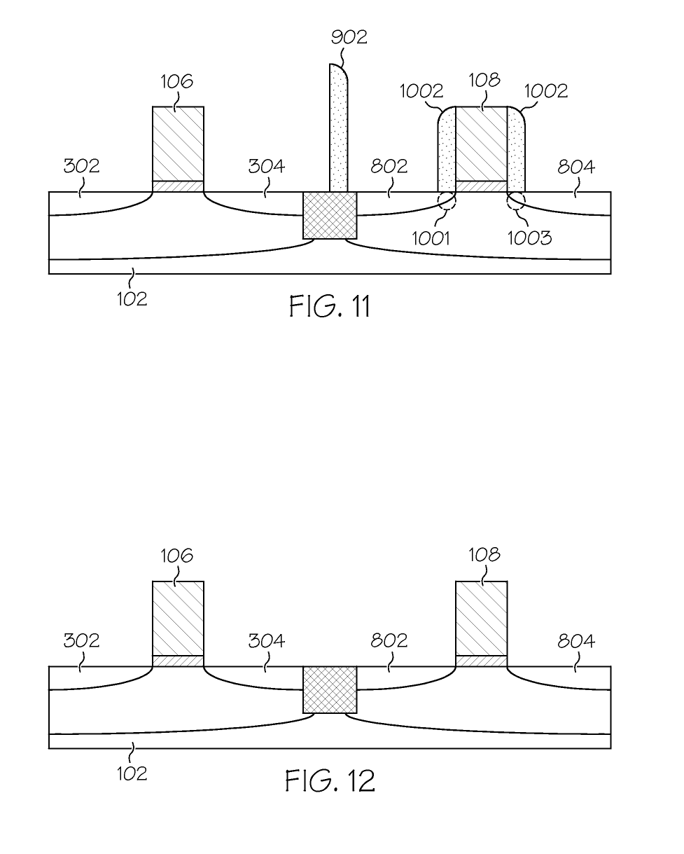

FIG. 11 illustrates the resultant structure following the removal of the photoresist material 806 (of FIG. 10) to expose the source and drain regions 302 and 304 and the gate stack 106. The photoresist material 806 may be removed using a similar etching process as discussed above in FIG. 6.

FIG. 12 illustrates the resultant structure following the removal of the spacer 1002 (of FIG. 11) and the residual protective spacer material 902 using a similar etching process as discussed above in FIG. 7.

The resultant structure includes the gate stack 106 with source and drain regions 302 and 304 that may have, for example, a n-type doping profile and a gate stack 108 with source and drain regions 802 and 804 that may have, for example, a p-type doping profile. Further processes may be performed to complete the formation of the FET devices, such as, for example, depositing and patterning spacers adjacent to the gate stacks 106 and 108 and performing an additional source and drain ion implantation and activation; and forming a silicide material over the source and drain regions 302, 304, 802, and 804.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A method for forming a field effect transistor device, the method comprising:
forming a first gate stack and a second gate stack on a substrate;
depositing a first photoresist material over the second gate stack and a portion of the substrate;
implanting ions in exposed regions of the substrate to define a first source region and a first drain region adjacent to the first gate stack;
depositing a first protective layer over the first source region, the first gate stack, the first drain region, and the first photoresist material;
removing portions of the first protective layer to expose the first photoresist material and to define a first spacer disposed on a portion of the first source region and a portion of the first drain region; and
removing the first photoresist material.

2. The method of claim 1, wherein the method includes removing the first spacer following the removal of the first photoresist material.

3. The method of claim 1, wherein the method further includes:
depositing a second photoresist material over the first gate stack and a portion of the substrate following the removal of the first spacer;
implanting ions in exposed regions of the substrate to define a second source region and a second drain region adjacent to the second gate stack;
depositing a second protective layer over the second source region, the second gate stack, the second drain region, and the second photoresist material;
removing portions of the second protective layer to expose the second photoresist material and to define a second spacer disposed on a portion of the second source region and a portion of the second drain region; and
removing the second photoresist material.

4. The method of claim 3, wherein the method includes removing the second spacer following the removal of the second photoresist material.

5. The method of claim 1, wherein the implanting ions in exposed regions of the substrate to define a first source region and a first drain region adjacent to the first gate stack includes implanting ions in the first photoresist layer, which is operative to form a hardened portion in the first photoresist layer.

6. The method of claim 1, wherein the first protective layer includes an oxide material.

7. The method of claim 1, wherein the first protective layer includes a nitride material.

8. The method of claim 1, wherein the first protective layer includes an organic polymer material.

9. The method of claim 1, wherein the portions of the first protective layer are removed with an anisotropic etching process.

10. The method of claim 1, wherein the portions of the first protective layer are removed with a reactive ion etching process.

11. The method of claim 1, wherein the first photoresist material is removed with an anisotropic etching process.

12. The method of claim 1, wherein the first spacer is removed with an isotropic etching process.

13. The method of claim 1, wherein the method further includes removing residual first protective layer material when removing the first spacer.

14. The method of claim 1, wherein the first gate stack includes an oxide layer disposed on the substrate and a polysilicon layer disposed on the oxide layer.

15. The method of claim 1, wherein the ions implanted in the first source region and the first drain region include n-type dopants.

16. The method of claim 1, wherein the ions implanted in the second source region and the second drain region include p-type dopants.

17. The method of claim 3, wherein the implanting ions in exposed regions of the substrate to define a second source region and a second drain region adjacent to the second gate stack includes implanting ions in the second photoresist layer, which is operative to form a hardened portion in the second photoresist layer.

18. A field effect transistor device prepared by a process comprising the steps of:
forming a first gate stack and a second gate stack on a substrate;
depositing a first photoresist material over the second gate stack and a portion of the substrate;
implanting ions in exposed regions of the substrate to define a first source region and a first drain region adjacent to the first gate stack;
depositing a first protective layer over the first source region, the first gate stack, the first drain region, and the first photoresist material;
removing portions of the first protective layer to expose the first photoresist material and to define a first spacer disposed on a portion of the first source region and a portion of the first drain region; and
removing the first photoresist material.

19. The field effect transistor device of claim 18, wherein the process further comprises removing the first spacer following the removal of the first photoresist material.

20. The field effect transistor device of claim 18, wherein the process further comprises:
depositing a second photoresist material over the first gate stack and a portion of the substrate following the removal of the first spacer;
implanting ions in exposed regions of the substrate to define a second source region and a second drain region adjacent to the second gate stack;
depositing a second protective layer over the second source region, the second gate stack, the second drain region, and the second photoresist material;
removing portions of the second protective layer to expose the second photoresist material and to define a second spacer disposed on a portion of the second source region and a portion of the second drain region;
removing the second photoresist material; and
removing the second spacer.
